(19) United States
(12) Patent Application Publication
(10) Pub. No.: US 2026/0206166 A1
(43) Pub. Date: Jul. 16, 2026

(54) POWER SUPPLY ASSEMBLY

(71) Applicant: LITE-ON TECHNOLOGY CORPORATION, Taipei (TW)

(72) Inventors: Min-Hao HSU, Taipei (TW); Ting-Yu SUNG, Taipei (TW); Eufracio Jr Miguel Sagun, Taipei (TW)

(21) Appl. No.: 19/424,206

(22) Filed: Dec. 18, 2025

Related U.S. Application Data
(60) Provisional application No. 63/743,684, filed on Jan. 10, 2025.

(30) Foreign Application Priority Data
Sep. 17, 2025 (CN) 202511326242.4

(51) Int. Cl. H05K 7/14

(52) U.S. Cl. CPC H05K 7/1432

(57) ABSTRACT

A power supply assembly is provided. The power supply assembly comprises a first sub-circuit board, a second sub-circuit board and a main control circuit board. The first sub-circuit board includes a first control module. The first control module includes a controller. The second sub-circuit board includes a second control module. The second control module includes a controller. The main control circuit board is provided for the first and second sub-circuit boards to be mounted on. The input/output pins of the first and second sub-circuit boards are electrically connected to the main control circuit board.

This application claims the benefit of the US provisional application Serial No. 63/743,684, filed Jan. 10, 2025, and the CN application Serial No. 202511326242.4, filed Sep. 17, 2025, the disclosures of which are incorporated by reference herein in its entirety.

### TECHNICAL FIELD

The present invention relates to a power supply assembly, and more particularly, to a power supply assembly having a modular digital control function.

### BACKGROUND

With the advancement of technology, contemporary power supply devices/equipment widely adopt a digital signal processor (DSP) or a microcontroller unit (MCU) as a core control unit to achieve high-precision voltage/current regulation, protection mechanisms, and communication functions. In such a configuration, the core control unit is typically directly integrated with the main control circuit board. However, when instability arises in the supply chain, or when specific brands or models of digital signal processors or microcontroller units become unavailable, the overall power supply design cannot be properly serviced or replaced, thereby adversely affecting product delivery schedules, maintenance efficiency, and supply chain flexibility.

However, prior art lacks a modular power configuration capable of supporting primary-side and/or secondary-side control while allowing controllers from multiple manufacturers to be used. Therefore, it is necessary to provide a highly compatible and modularly designed power supply assembly that supports primary-side, and/or secondary-side, and even tertiary-side control functions, so as to meet the demands of modern power systems for reliability, maintainability, and supply flexibility.

### SUMMARY

The present disclosure relates to a power supply assembly, and more particularly to a power control configuration that provides modular digital control functionality and supports control modules from different manufacturers. Through such a configuration, system design flexibility and component substitutability are enhanced so as to address risks associated with supply chain shortages and the upgrade requirements of control units.

According to an aspect of the present invention, a power supply assembly is provided. The power supply assembly comprises a first sub-circuit board, a second sub-circuit board and a main control circuit board. The first sub-circuit board includes a first control module. The first control module includes a controller. The second sub-circuit board includes a second control module. The second control module includes a controller. The main control circuit board is provided for the first and second sub-circuit boards to be mounted on. The input/output pins of the first and second sub-circuit boards are electrically connected to the main control circuit board.

The above summary is not intended to represent all embodiments or all aspects of the present invention. On the contrary, the above summary is merely provided as some examples illustrating novel aspects and features of the present invention. In order to make the embodiments and other objects, features, and advantages of the present invention more apparent and understandable, preferred embodiments are described in detail below with reference to the accompanying drawings. After the detailed description of various embodiments with reference to the drawings, those skilled in the art will be more able to understand other aspects of the present invention. A brief description of the drawings is provided as follows.

### BRIEF DESCRIPTION OF THE DRAWINGS

FIG. 1 illustrates a system block diagram of a power supply assembly according to an embodiment of the present invention.

FIG. 2A illustrates a perspective view of a power supply assembly according to an embodiment of the present invention.

FIG. 2B illustrates a perspective view of the power supply assembly of FIG. 2A from another view angle.

FIG. 2C illustrates a top view of the power supply assembly of FIG. 2B.

FIG. 3A illustrates a perspective view of a power supply assembly according to another embodiment of the present disclosure.

FIG. 3B illustrates a perspective view of the power supply assembly of FIG. 3A from another view angle.

FIG. 3C illustrates a plan view of the power supply assembly of FIG. 3A.

FIG. 4A illustrates a plan view of a first sub-circuit board of the power supply assembly.

FIG. 4B illustrates a plan view of a second sub-circuit board of the power supply assembly.

### DETAILED DESCRIPTION

Detailed descriptions of the embodiments of the specification are disclosed below with reference to the accompanying drawings. Apart from the detailed descriptions provided, any embodiments in which the present invention can be used as well as any substitutions, modifications or equivalent changes of the said embodiments are within the scope of the disclosure, and the descriptions and definitions in the claims shall prevail. In the following detailed description, for purposes of explanation, numerous specific details are set forth in order to provide a thorough understanding of the disclosed embodiments. It will be apparent, however, that one or more embodiments may be practiced without these specific details. Additionally, well-known common steps or components are not described in detail to avoid unnecessarily limiting the present invention. The same or similar elements in the figures are represented by the same or similar symbols. It is important to note that the drawings are for illustration purposes only and do not represent the actual size or quantity of components, unless otherwise specified.

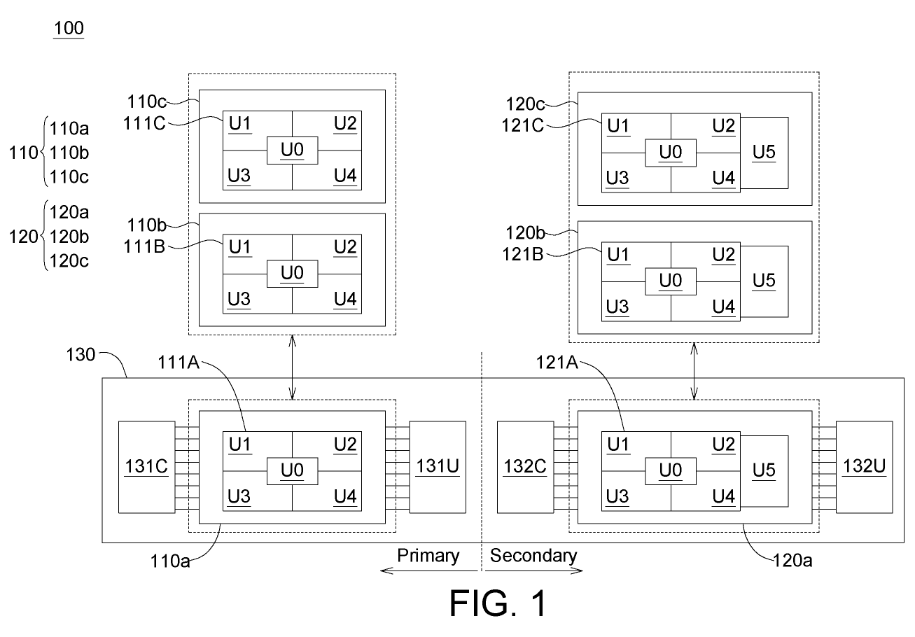

Please refer to FIG. 1, which illustrates a system block diagram of a power supply assembly 100 according to an embodiment of the present disclosure.

The power supply assembly 100 may be, for example, a power supply unit (PSU). As shown in FIG. 1, the power supply assembly 100 may comprise a first sub-circuit board 110, a second sub-circuit board 120, and a main control circuit board 130. The first sub-circuit board 110 and the second sub-circuit board 120 are independently mounted on the main control circuit board 130, such that these two sub-circuit boards are separate. In the present embodiment, the first sub-circuit board 110 and the electronic components disposed thereon are configured for primary-side control, while the second sub-circuit board 120 and the electronic components disposed thereon are configured for secondary-side control. The main control circuit board 130 includes a first critical circuit 131C and a first non-critical circuit 131U for the primary side, and a second critical circuit 132C and a second non-critical circuit 132U for the secondary side. The term “critical circuit” refers to circuits directly associated with core functions such as power control, safety protection, and power conversion. The term “non-critical circuit” refers to peripheral functional circuits not directly involved in power conversion or safety control. As shown in FIG. 1, the first sub-circuit board 110 is electrically connected to the first critical circuit 131C (e.g., input/output voltage and current sensors, control circuits of a boost module) and the first non-critical circuit 131U (e.g., DSP programming circuits, communication circuits between the primary and secondary sides, temperature sensing circuits, processor power supply circuits). Similarly, the second sub-circuit board 120 is electrically connected to the second critical circuit 132C (e.g., DC-DC converter, input/output voltage and current sensors, control circuits of an auxiliary power module) and the second non-critical circuit 132U (e.g., DSP programming circuits, primary/secondary communication circuits, temperature sensing circuits, processor power-supply circuits, communication circuits between the power supply and the system, power status monitoring circuits).

Specifically, the first sub-circuit board 110 is provided with a first control module, which may be selected from multiple control modules having primary-side control functionality and different specifications. The second sub-circuit board 120 is provided with a second control module, which may be selected from multiple control modules having secondary-side control functionality and different specifications. The first and second control modules may include controllers, such as a digital signal processor (DSP) or a microcontroller unit (MCU). The controllers of the first and second control modules may correspond to processor products from different manufacturers (e.g., Texas Instruments, Microchip, STMicroelectronics), and the modular design allows for differences in specifications (e.g., package types, pin configurations, communication protocols), thereby providing flexible configurability. In an embodiment, the controllers of the first control module and the controllers of the second control module are derived from different manufacturers, and thus their total number of pins may be the same or different. For example, when the total number of pins differs, the controller of the first control module may have 48 or 64 pins, whereas the controller of the second control module may have 80 or 100 pins. Accordingly, the size of the primary-side control module is typically smaller than that of the secondary-side control module. Alternatively, when both controllers have the same total number of pins, the controller of the first control module may have 48 or 64 pins, and the controller of the second control module may likewise have 48 or 64 pins. The present disclosure does not limit the pin count of the controllers of the first and second control modules.

In the present disclosure, referring to the primary-side configuration shown in FIG. 1, a first sub-circuit board 110a including a first control module 111A may be disposed on the main control circuit board 130. The first sub-circuit board 110a may be modularly replaced with a first sub-circuit board 110b including a first control module 111B, or a first sub-circuit board 110c including a first control module 111C. The controllers of the first control modules 111A, 111B, and 111C are derived from different manufacturers, and the first sub-circuit boards 110a to 110c share identical input/output interfaces for electrical or communication connection to the main control circuit board 130. Similarly, for the secondary side shown in FIG. 1, a second sub-circuit board 120a including a second control module 121A may be disposed on the main control circuit board 130. The second sub-circuit board 120a may be modularly replaced with a second sub-circuit board 120b including a second control module 121B, or a second sub-circuit board 120c including a second control module 121C. The controllers of the second control modules 121A, 121B, and 121C are also derived from different manufacturers, and the second sub-circuit boards 120a to 120c likewise share identical input/output interfaces for electrical or communication connection to the main control circuit board 130. Accordingly, by mapping different specifications of first and second control modules (i.e., control modules selected from multiple primary-side or secondary-side modules with differing configurations) to unified input/output interfaces via the first and second sub-circuit boards, the circuitry on the main control circuit board requires no modification when switching between controller modules from different manufacturers. Thus, the power supply assembly of the present disclosure satisfies modern requirements for system reliability, maintainability, and supply-chain flexibility.

Specifically, the first control module (e.g., the first control modules 111A, 111B or 111C) may include a controller U0, an analog-to-digital converter (ADC) control circuit U1, a voltage supply circuit (or controller voltage supply circuit) U2, a layout circuit (or controller/microcontroller layout circuit) U3, and a programming circuit U4. Similarly, the second control module (e.g., the second control modules 121A, 121B, or 121C) may include a controller U0, an ADC control circuit U1, a voltage supply circuit U2, a layout circuit U3, and a programming circuit U4, and may further optionally include a security unit U5. In the configuration of the first and second control modules, each ADC control circuit U1, voltage supply circuit U2, layout circuit U3, programming circuit U4, and security unit U5 may be coupled to the controller U0, such that the controller U0 provides the corresponding functions through these circuits or units. The term “coupled” refers to the presence of an electrical connection, signal linkage, or functional association between two elements, and may include direct electrical connection or indirect connection through one or more intermediary components or circuit structures, without limitation to a specific connection topology.

In an embodiment, the controller U0, the ADC control circuit U1, the voltage supply circuit U2, the layout circuit U3, the programming circuit U4, and the security unit U5 may each be implemented as a concrete circuit structure comprising one or more transistors, resistors, capacitors, integrated circuits (ICs), digital logic elements, or microcontroller modules to achieve their respective functions. For example, the controller U0 may be a DSP IC used to execute control algorithms and digital computations. The ADC control circuit U1 may include an analog-to-digital (ADC) sampling circuit and a digital-to-analog converter (DAC) circuit, both of which include first-order filtering functionality. The voltage supply circuit U2 may include passive components required for power supply, such as voltage‑stabilizing capacitors and filter inductors. The layout circuit U3 may include hardware configuration circuits associated with grounding, diffraction, noise isolation, or signal routing design, such that through the layout design, the input/output pins of controllers U0 from different manufacturers are normalized or standardized across the first sub-circuit boards 110a to 110c and the second sub-circuit boards 120a to 120c. The programming circuit U4 may be implemented as a programming control circuit via communication interfaces or communication protocols within the electronic circuitry. The security unit U5 may be implemented by one or more security ICs, firmware control modules, or combinations thereof, to perform authentication or protection functions and support components from different manufacturers.

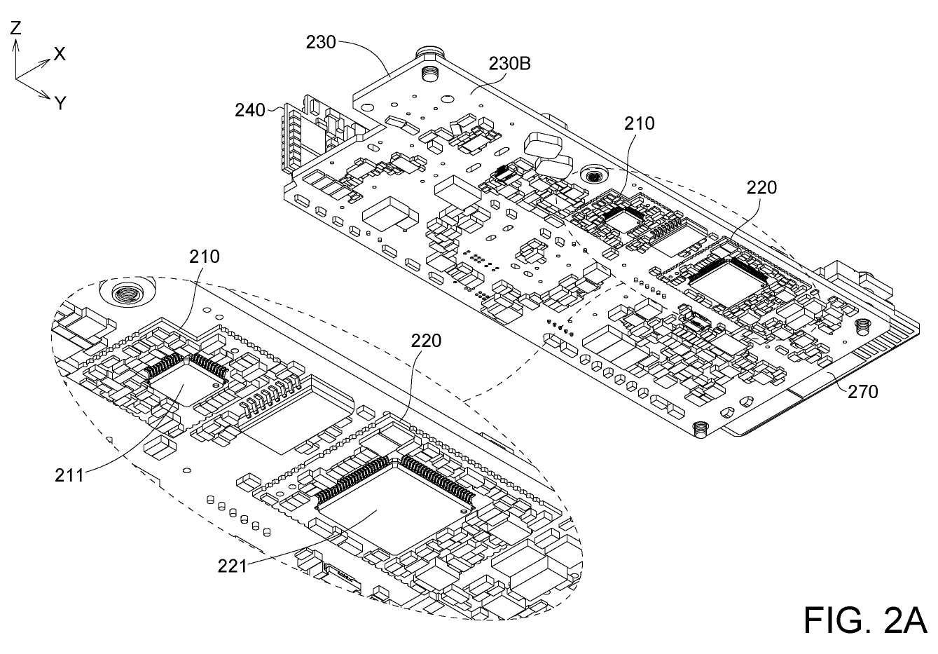

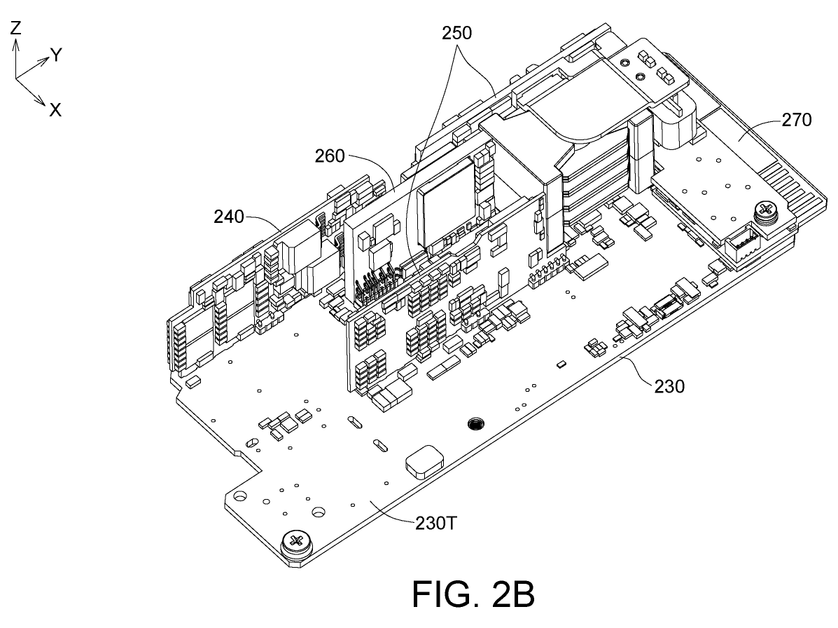

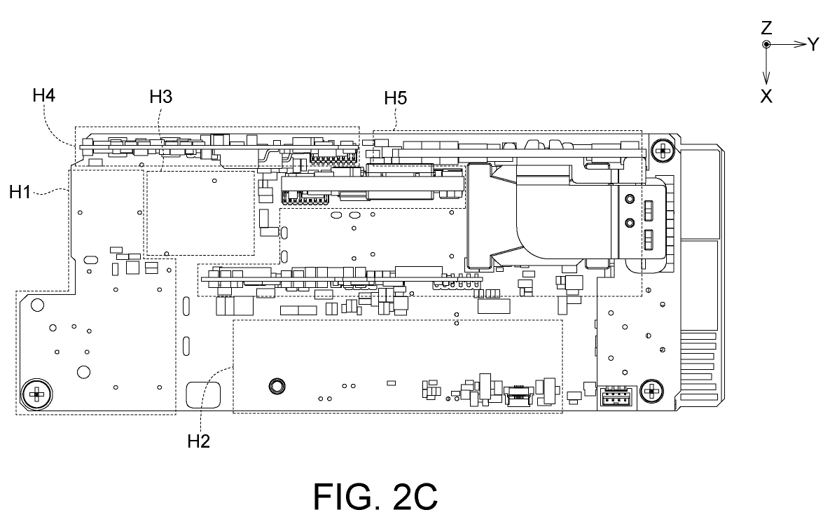

Referring to FIGS. 2A to 2C, FIG. 2A illustrates a perspective view of a power supply assembly 200 according to an embodiment of the present disclosure, FIG. 2B illustrates another perspective view of the power supply assembly 200, and FIG. 2C illustrates a top view of the power supply assembly 200.

As shown in FIGS. 2A and 2B, the power supply assembly 200 may include a first sub-circuit board 210, a second sub-circuit board 220, and a main control circuit board 230. The first sub-circuit board 210 includes a first control module 211, which may be selected from a plurality of control modules having primary-side control functionality and configured in different specifications (such as the foregoing first control modules 111A, 111B, or 111C). The second sub-circuit board 220 includes a second control module 221, which may be selected from a plurality of control modules having secondary-side control functionality and configured in different specifications (such as the foregoing second control modules 121A, 121B, or 121C). The main control circuit board 230 has an upper surface 230T and a lower surface 230B opposite thereto, wherein what FIG. 2A illustrates is from a bottom view angle toward the lower surface 230B, and what FIG. 2B illustrates is from a top view angle toward the upper surface 230T. As shown in FIG. 2A, the first sub-circuit board 210 and the second sub-circuit board 220 are disposed on the lower surface 230B of the main control circuit board 230. In this embodiment, the first sub-circuit board 210 and the second sub-circuit board 220 are directly assembled onto the main control circuit board 230. Specifically, the first sub-circuit board 210 and the second sub-circuit board 220 may be mounted to the main control circuit board 230 by surface-mount-technology (SMT).

Referring to FIGS. 2A to 2C, the power supply assembly 200 may further include an electromagnetic interference suppression module (not shown in the figures and which may be disposed in region H1 as shown in FIG. 2C), capacitors (not shown and which may be disposed in region H2), magnetic elements (not shown and which may be disposed in region H3), a boost module 240 (which may be disposed in region H4), a converter module 250 (including multiple magnetic elements (not shown) and converter circuits and which may be disposed in region H5), a standby module 260, and a power connection module 270. The boost module 240, the converter module 250, the standby module 260, and the power connection module 270 are coupled to the main control circuit board 230. The boost module 240 may be applied to a DC-DC converter, or may serve as a power-factor-correction (PFC) boost module applied to an AC-DC converter. The converter module 250 may be implemented as a DC-DC converter or an AC-DC converter. The term “coupled” refers to the presence of electrical connection, signal communication, or functional association between two components, wherein the coupling may be a direct electrical connection or an indirect connection through one or more intermediary components or circuit structures, and is not limited to a specific connection topology.

As shown in FIGS. 2B and 2C, the electromagnetic interference suppression module, the capacitors, the magnetic elements, the boost module 240, the converter module 250, the standby module 260, and the power connection module 270 are disposed on the upper surface 230T of the main control circuit board 230, i.e., on a side opposite to where the first sub-circuit board 210 and the second sub-circuit board 220 are mounted. In this embodiment, the electromagnetic interference suppression module is disposed in region H1 as shown in FIG. 2C, the capacitors are disposed in region H2, the standby module 260 is located between the boost module 240 and the converter module 250, and the power connection module 270 is disposed at one side (edge) of the main control circuit board 230. The boost module 240, the converter module 250, and the standby module 260 may be inserted into the main control circuit board 230 so as to be mounted in an upright orientation. The power connection module 270 may be fixed to the main control circuit board 230 through screw fastening and is arranged in parallel with the main control circuit board 230.

The electromagnetic interference suppression module may include components such as a common-mode inductor, a differential-mode inductor, and filtering capacitors, and is configured to suppress high-frequency noise to prevent electromagnetic interference (EMI) from affecting external equipment or systems. The boost module 240 may include components such as a boost inductor, switching devices, a rectifier, and filtering capacitors, and is configured to perform power-factor correction (PFC) on the rectified DC power derived from an AC input while simultaneously performing boost voltage conversion. The converter module 250 may include components such as a buck inductor, switching devices, rectifying diodes, filtering capacitors, and control circuits, and is configured to convert the DC voltage obtained after power-factor correction into one or more stable DC output voltages for powering loads. The standby module 260 may include components such as a low-power transformer and switching devices, and is configured to provide a low-power output for maintaining operation of critical circuits when the system is in a standby state. The power connection module 270 may include gold fingers, connector terminals, soldering interfaces, or other suitable connection elements, and is configured to output the DC output voltage generated after DC power conversion to external equipment such as servers or load modules.

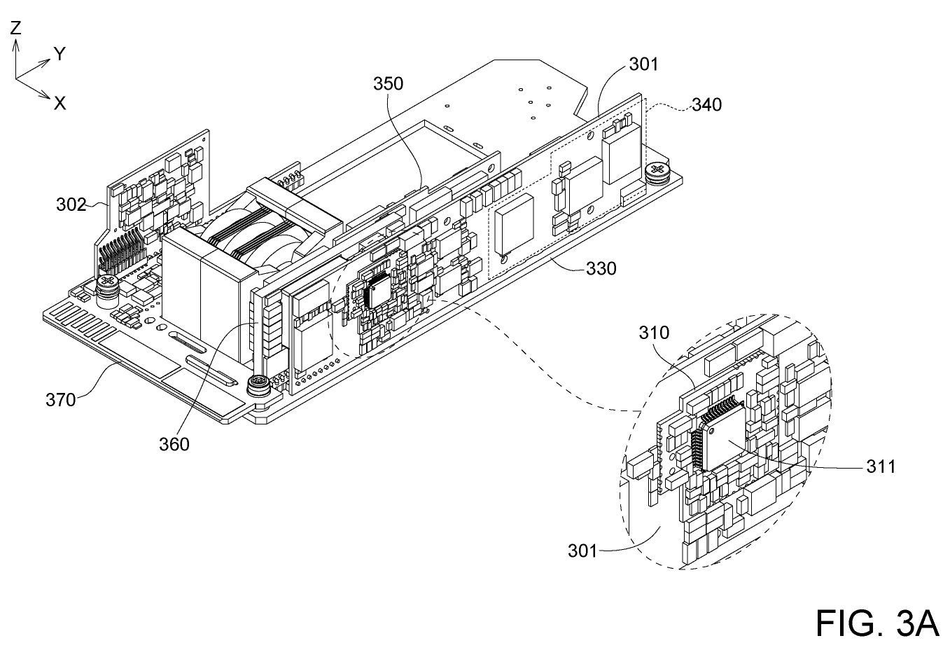

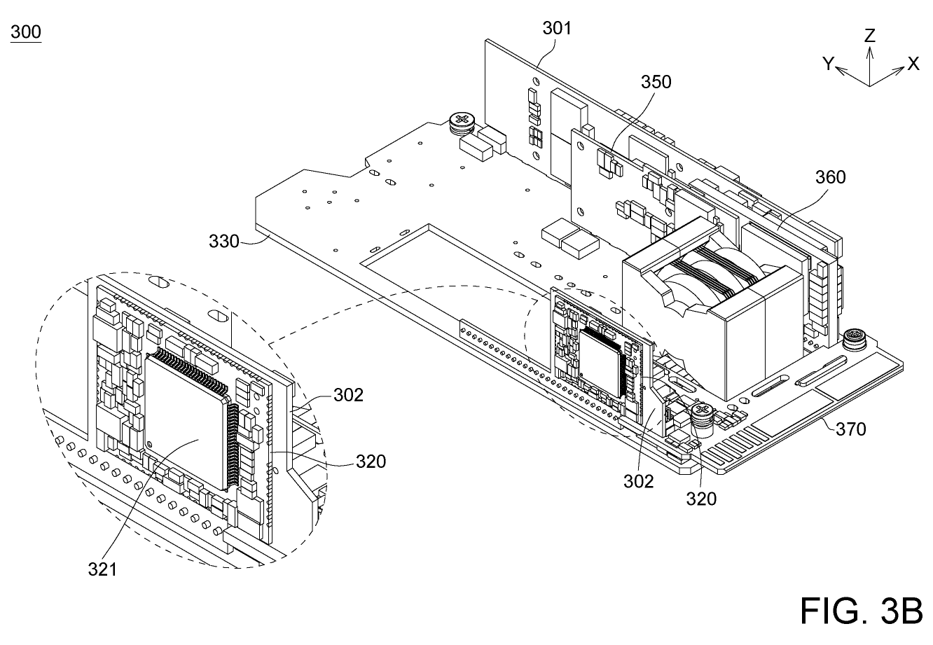

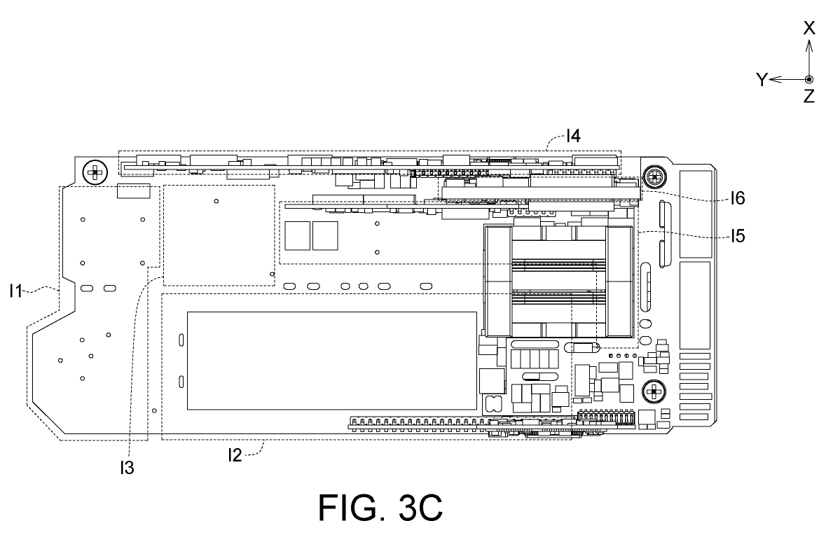

Referring to FIGS. 3A to 3C, FIG. 3A illustrates a perspective view of a power supply assembly 300 according to an embodiment of the present disclosure, FIG. 3B illustrates another perspective view of the power supply assembly 300, and FIG. 3C illustrates a plan view of the power supply assembly 300. In contrast to the configuration shown in FIGS. 2A to 2C, in which the first sub-circuit board 210 and the second sub-circuit board 220 are directly mounted on the main control circuit board 230, the embodiment shown in FIGS. 3A to 3C provides another feasible configuration.

As shown in FIGS. 3A and 3B, the power supply assembly 300 may comprise a first sub-circuit board 310, a second sub-circuit board 320, and a main control circuit board 330. FIG. 3A shows the perspective from which the first sub-circuit board 310 is visible, while FIG. 3B shows the perspective from which the second sub-circuit board 320 is visible. The first sub-circuit board 310 includes a first control module 311, which may be selected from multiple control modules having primary-side control functions and different specification configurations (e.g., the aforementioned control modules 111A, 111B, or 111C). The second sub-circuit board 320 includes a second control module 321, which may be selected from multiple control modules having secondary-side control functions and different specification configurations (e.g., the aforementioned control modules 121A, 121B, or 121C). As shown in FIG. 3A, the first sub-circuit board 310 is mounted on a first intermediate circuit board 301. As shown in FIG. 3B, the second sub-circuit board 320 is mounted on a second intermediate circuit board 302. Specifically, the first sub-circuit board 310 and the second sub-circuit board 320 may be mounted on the first intermediate circuit board 301 and the second intermediate circuit board 302, respectively, via surface-mount-technology (SMT). The first intermediate circuit board 301 and the second intermediate circuit board 302 are mounted on the main control circuit board 330. In particular, the first and second intermediate circuit boards 301 and 302 may be inserted into the main control circuit board 330 for upright installation.

The power supply assembly 300 may further comprise an electromagnetic interference suppression module (not shown, and may be disposed in region I1 shown in FIG. 3C), capacitors (not shown, and may be disposed in region I2), magnetic components (not shown, and may be disposed in region I3), a boost module 340 (not shown, and may be disposed in region I4), a converter module 350 (not shown, and may be disposed in region I5), a standby module 360 (not shown, and may be disposed in region I6), and a power connection module 370. The electromagnetic interference suppression module, the boost module 340, the converter module 350, the standby module 360, and the power connection module 370 are coupled to the main control circuit board 330. The term “coupled” refers to the existence of electrical connection, signal communication, or functional association between two components. The coupling may be a direct electrical connection or an indirect connection through one or more intermediary components or circuit structures, and is not limited to any specific connection topology. The constituent elements and functions of the above modules may be configured and implemented in the same or similar manner as those described in the embodiment of the power supply assembly 200. Therefore, repeated description is omitted for conciseness.

In the present embodiment, the boost module 340 is included in the second intermediate circuit board 302. That is, the first sub-circuit board 310 may share the same carrier board with the electromagnetic interference suppression module, and the second sub-circuit board 320 may share the same carrier board with the boost module 340. However, the present disclosure is not limited to this arrangement. In other embodiments, the boost module 340, the converter module 350, the standby module 360, or the power connection module 370 may alternatively be included in the first intermediate circuit board 301; and/or the electromagnetic interference suppression module, the converter module 350, the standby module 360, or the power connection module 370 may be included in the second intermediate circuit board 302. In other words, any two modules selected from the group consisting of the electromagnetic interference suppression module, the boost module 340, the converter module 350, the standby module 360, and the power connection module 370 may be respectively included in the first intermediate circuit board 301 and the second intermediate circuit board 302.

As shown in FIGS. 3A and 3B, the standby module 360 is disposed between the boost module 340 and the converter module 350. The power connection module 370 is disposed at a side (edge) of the main control circuit board 330. The first sub-circuit board 310 and the second sub-circuit board 320 may be located at opposite sides of the main control circuit board 330. The first sub-circuit board 310 may be disposed adjacent to the standby module 360, and the second sub-circuit board 320 may be disposed adjacent to the power connection module 370. The boost module 340 may be mounted on the first intermediate circuit board 301 via surface mount technology, and the first intermediate circuit board 301 may then be inserted into the main control circuit board 330. The converter module 350 and the standby module 360 may be inserted into the main control circuit board 330 for upright installation. The power connection module 370 may be secured to the main control circuit board 330 through screw fastening and is arranged parallel to the main control circuit board 330.

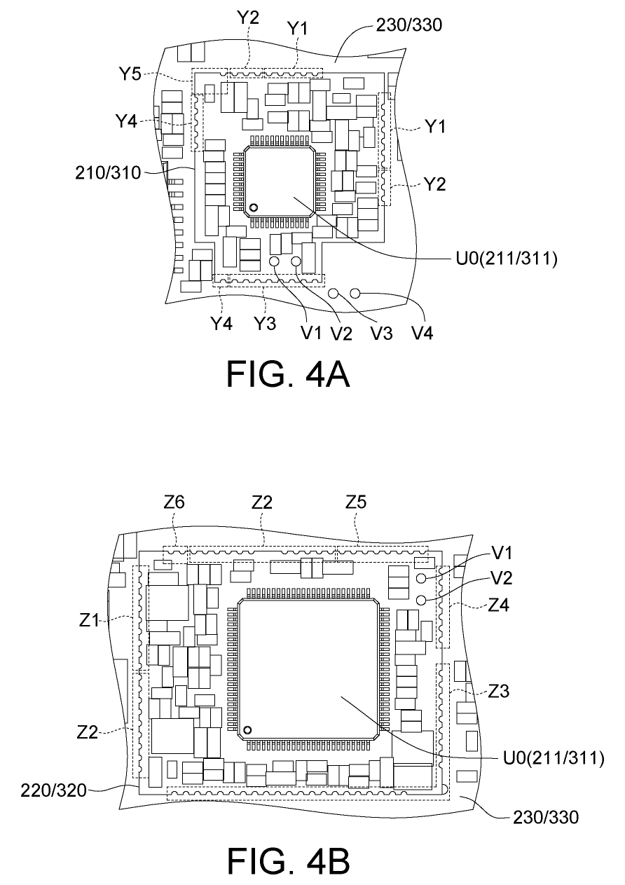

Referring to FIGS. 4A and 4B, FIG. 4A illustrates the first sub-circuit boards 210 and 310 applicable to the aforementioned embodiments of the power supply assemblies 200 and 300, and FIG. 4B illustrates the second sub-circuit boards 220 and 320 applicable to the power supply assemblies 200 and 300. Additionally, reference is made to FIG. 1.

As shown in FIG. 4A, the input/output pins of the first sub-circuit boards 210/310 are divided into pin regions corresponding to different functions, and the first sub-circuit boards 210/310 are electrically connected to the main control circuit boards 230/330 through these pin regions. Specifically, the first pin regions Y1 are electrically connected to the layout circuit U3, and the first pin regions Y1 are further electrically connected to the pins of the controller U0 used for feedback sensing-related functions. The second pin regions Y2 are electrically connected to the ADC converter control circuit U1, and the second pin regions Y2 are further electrically connected to the pins of the controller U0 used for converter control-related functions. The third pin region Y3 is electrically connected to the programming circuit U4, and the third pin region Y3 is further electrically connected to the pins of the controller U0 used for programming communication-related functions. The fourth pin regions Y4 are electrically connected to the layout circuit U3,and the fourth pin regions Y4 are further electrically connected to the pins of the controller U0 used for primary-side and secondary-side communication-related functions. The fifth pin region Y5 is electrically connected to the voltage supply circuit U2,and the fifth pin region Y5 is further electrically connected to the pins of the controller U0 used for power supply-related functions.

Regarding the positional arrangement, the first pin regions Y1 are adjacent to the second pin regions Y2; one of the second pin regions Y2 (upper side in FIG. 4A) is adjacent to one of the first pin regions Y1 and the fifth pin region Y5, and is disposed between the one of the first pin region Y1 and the fifth pin region Y5; another one of second pin regions Y2 (right side in FIG. 4A) is adjacent to another one of the first pin regions Y1. The third pin region Y3 is adjacent to one of the fourth pin regions Y4 (lower side in FIG. 4A). Another one of the fourth pin regions Y4 (left side in FIG. 4A) is adjacent to the fifth pin region Y5. The fifth pin region Y5 is adjacent to one of the second pin regions Y2 (upper side in FIG. 4A) and the another one of the fourth pin regions Y4 (left side in FIG. 4A). The first pin region Y1 and the second pin region Y2 (both on the right side in FIG. 4A) are opposite to the fourth pin region Y4 (left side in FIG. 4A). The third pin region Y3 and the fourth pin region Y4 (both on the lower side in FIG. 4A) are opposite to the first pin region Y1, the second pin region Y2, and the fifth pin region Y5 (all on the upper side in FIG. 4A).

In an embodiment, the pins of the controller U0 used for feedback sensing-related functions have a first distance to any of the first pin regions Y1 (upper or right side in FIG. 4A); the pins of the controller U0 used for converter control-related functions have a second distance to any of the second pin regions Y2 (upper or right side in FIG. 4A); the pins of the controller U0 used for programming communication-related functions have a third distance to the third pin region Y3; the pins of the controller U0 used for primary-side and secondary-side communication-related functions have a fourth distance to any of the fourth pin regions Y4 (lower or left side in FIG. 4A); and the pins of the controller U0 used for power supply-related functions have a fifth distance to the fifth pin region Y5. The first distance is less than or equal to the fifth distance, and the fifth distance is less than the second, third, or fourth distances. Specifically, the first to fifth distances may be defined as the circuit path distance between the controller U0 and each pin region (Y1 to Y5), or as the physical distance between the edge of the controller U0 and each pin region (Y1 to Y5), without limitation.

It should be noted that, to ensure multiple first sub-circuit boards have identical input/output, each pin region (Y1 to Y5) must be consistent. Since the pin layouts of controllers U0 derived from different manufacturers are not identical, the circuit layout must be designed according to the function of each pin of the controller U0, sequentially planning the shortest distance to each pin region (Y1 to Y5). For example, the first distance between the pins of the controller U0 used for feedback sensing-related functions and the first pin region Y1 is the shortest to shorten signal paths and improve control accuracy; the fifth distance between the pins of the controller U0 used for power supply-related functions and the fifth pin region Y5 is the second shortest to reduce power interference and improve stability; and the second, third, and fourth distances are laid out according to their shortest achievable distance based on the pins of controllers U0 derived from different manufacturers, without limitation.

As shown in FIG. 4B, the input/output pins of the second sub-circuit boards 220/320 are divided into pin regions corresponding to different functions, and the second sub-circuit boards 220/320 are electrically connected to the main control circuit boards 230/330 through these pin regions. Specifically, the first pin region Z1 is electrically connected to the layout circuit U3, and the first pin region Z1 is further electrically connected to the pins of the controller U0 used for feedback sensing-related functions. The second pin regions Z2 are electrically connected to the layout circuit U3, and the second pin regions Z2 are further electrically connected to the pins of the controller U0 used for pulse-width modulation (PWM)-related functions. The third pin region Z3 is electrically connected to the layout circuit U3, and the third pin region Z3 is further electrically connected to the pins of the controller U0 used for power supply and system monitoring-related functions. The fourth pin region Z4 is electrically connected to the programming circuit U4, and the fourth pin region Z4 is further electrically connected to the pins of the controller U0 used for programming communication-related functions. The fifth pin region Z5 is electrically connected to the layout circuit U3, and the fifth pin region Z5 is further electrically connected to the pins of the controller U0 used for primary-side and secondary-side communication-related functions. The sixth pin region Z6 is electrically connected to the voltage supply circuit U2, and the sixth pin region Z6 is further electrically connected to the pins of the controller U0 used for power supply-related functions.

Regarding the positional arrangement, the first pin region Z1 is adjacent to one of the second pin regions Z2 (left side in FIG. 4B) and the sixth pin region Z6. Another one of the second pin regions Z2 (upper side in FIG. 4B) is adjacent to the fifth pin region Z5 and the sixth pin region Z6, and is disposed between the fifth pin region Z5 and the sixth pin region Z6. The one of the second pin regions Z2 (left side in FIG. 4B) is adjacent to the first pin region Z1 and the third pin region Z3. The third pin region Z3 (L-shaped) is adjacent to the one of the second pin regions Z2 (left side in FIG. 4B) and the fourth pin region Z4. The fourth pin region Z4 is adjacent to the third pin region Z3 and the fifth pin region Z5. The fifth pin region Z5 is adjacent to the another one of the second pin regions Z2 (upper side in FIG. 4B) and the fourth pin region Z4. The sixth pin region Z6 is adjacent to the first pin region Z1 and the another one of the second pin regions Z2 (upper side in FIG. 4B). The first pin region Z1 and the one of the second pin regions Z2 (left side in FIG. 4B) are opposite to the third pin region Z3 and the fourth pin region Z4. The another one of the second pin regions Z2 (left side in FIG. 4B), the fifth pin region Z5, and the sixth pin region Z6 are opposite to the third pin region Z3.

In an embodiment, the pins of the controller U0 used for feedback sensing-related functions have a sixth distance to the first pin region Z1; the pins of the controller U0 used for pulse-width modulation-related functions have a seventh distance to the second pin regions Z2; the pins of the controller U0 used for power supply and system monitoring-related functions have an eighth distance to the third pin region Z3; the pins of the controller U0 used for programming communication-related functions have a ninth distance to the fourth pin region Z4; the pins of the controller U0 used for primary-side and secondary-side communication-related functions have a tenth distance to the fifth pin region Z5; and the pins of the controller U0 used for power supply-related functions have an eleventh distance to the sixth pin region Z6. The sixth, seventh, and eighth distances are less than or equal to the eleventh distance. The eleventh distance is less than the ninth or tenth distances. Specifically, the sixth to eleventh distances may be defined as the circuit path distance between the controller U0 and each pin region (Z1 to Z6), or as the physical distance between the edge of the controller U0 and each pin region (Z1 to Z6), without limitation.

It should be noted that, as described above, in order for multiple second sub-circuit boards to have the same input/output configuration, each pin region (first pin region Z1 to sixth pin region Z6) must be consistent. Moreover, the pin design positions of controllers U0 from different manufacturers vary. Accordingly, in the circuit layout design, the shortest distances between the pins of the controller U0 and each pin region (first pin region Z1 to sixth pin region Z6) are sequentially planned according to the functions of the pins of controller U0. For example, the sixth distance, seventh distance, and eighth distance between the pins of controller U0 used for feedback sensing, pulse-width modulation, and power supply/system monitoring-related functions and the corresponding pin regions (first pin region Z1 to third pin region Z3) are set to be the shortest to reduce signal path length and enhance control accuracy. The relative lengths among the sixth distance, seventh distance, and eighth distance are not limited herein. The eleventh distance between the pins of controller U0 used for power supply-related functions and the sixth pin region Z6 is set as the second shortest distance to reduce power supply interference and improve stability, wherein the eleventh distance is longer than the sixth, seventh, or eighth distance. The ninth distance and tenth distance are arranged according to their shortest achievable distances based on the pin configuration of different manufacturers’ controllers U0, without limitation.

In another embodiment, as shown in FIGS. 2A, 4A, and 4B, the first sub-circuit boards 210, 310 and the second sub-circuit boards 220, 320 each include programming holes V1, V2 electrically connected to the programming circuit U4, and the main control circuit boards 230, 330 also include programming holes V3, V4 electrically connected to the programming circuit U4. Accordingly, the programming holes V1, V2 allow a user to directly program the first sub-circuit boards 210, 310 and the second sub-circuit boards 220, 320. Alternatively, after the first sub-circuit boards 210 and the second sub-circuit boards 220 are installed on the main control circuit board 230, the programming holes V3, V4 of the main control circuit board 230 allow the user to indirectly program the first sub-circuit boards 210 and the second sub-circuit boards 220. Additionally, after the first sub-circuit board 310 or the second sub-circuit board 320 is installed on the main control circuit board 330 via the first intermediate circuit board 301 or the second intermediate circuit board 302, the programming holes of the main control circuit board 330 (not shown) allow the user to indirectly program the first sub-circuit board 310 and the second sub-circuit board 320. Therefore, by designing the programming holes V1 to V4, users can conveniently select the most suitable method for programming the controller U0.

According to the above description, the present disclosure provides a novel power supply assembly, in which a first sub-circuit board and a second sub-circuit board, designed to be installable on a main control circuit board, are provided. The first sub-circuit board includes a first control module selected from multiple control modules having primary-side control functions and different specifications, and the second sub-circuit board includes a second control module selected from multiple control modules having secondary-side control functions and different specifications. This arrangement achieves modular digital control functionality and supports power control architectures derived from control modules of different manufacturers, thereby enhancing system design flexibility and component interchangeability to address potential supply chain shortages of parts/components and updates of control units.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A power supply assembly, comprising:
a first sub-circuit board including a first control module, wherein the first control module comprises a controller;
a second sub-circuit board including a second control module, wherein the second control module comprises a controller; and
a main control circuit board on which the first sub-circuit board and the second sub-circuit board are disposed, wherein the input/output pins of the first sub-circuit board and the second sub-circuit board are electrically connected to the main control circuit board.

2. The power supply assembly of claim 1, wherein the first control module is selected from a plurality of control modules having primary-side control functions and different specification configurations, and the second control module is selected from a plurality of control modules having secondary-side control functions and different specification configurations.

3. The power supply assembly of claim 1, wherein the first sub-circuit board and the second sub-circuit board are directly disposed on and electrically connected to the main control circuit board.

4. The power supply assembly of claim 1, further comprising a first intermediate circuit board and a second intermediate circuit board, wherein the first sub-circuit board is disposed on and electrically connected to the main control circuit board via the first intermediate circuit board, and the second sub-circuit board is disposed on and electrically connected to the main control circuit board via the second intermediate circuit board.

5. The power supply assembly of claim 1, wherein the first sub-circuit board is selected from a plurality of circuit boards used for primary-side control, the plurality of circuit boards used for primary-side control have identical input and output pin configurations for electrical connection to the main control circuit board, the second sub-circuit board is selected from a plurality of circuit boards used for secondary-side control, and the plurality of circuit boards used for secondary-side control have identical input and output pin configurations for electrical connection to the main control circuit board.

6. The power supply assembly of claim 1, further comprising a boost module, a converter module, a standby module, and a power connection module, and the boost module, the converter module, the standby module and the power connection module are electrically connected to the main control circuit board.

7. The power supply assembly of claim 1, wherein the first control module further comprises an analog-to-digital converter control circuit, a voltage supply circuit, a layout circuit, and a programming circuit, and wherein the analog-to-digital converter control circuit, the voltage supply circuit, the layout circuit and the programming circuit are each electrically connected to the controller of the first control module.

8. The power supply assembly of claim 1, wherein the second control module further comprises an analog-to-digital converter control circuit, a voltage supply circuit, a layout circuit, a programming circuit, and a safety unit, and wherein the analog-to-digital converter control circuit, the voltage supply circuit, the layout circuit, the programming circuit and the safety unit are each electrically connected to the controller of the second control module.

9. The power supply assembly of claim 1, wherein the input/output pins of the first sub-circuit board are divided into a first pin region, a second pin region, a third pin region, a fourth pin region, and a fifth pin region, and the first pin region, the second pin region, the third pin region, the fourth pin region, and the fifth pin region are respectively electrically connected to the controller of the first control module.

10. The power supply assembly of claim 9, wherein a distance between the controller of the first control module and the first pin region is less than or equal to a distance between the controller of the first control module and the fifth pin region, and the distance between the controller of the first control module and the fifth pin region is less than a distance between the controller of the first control module and the second pin region, a distance between the controller of the first control module and the third pin region, and a distance between the controller of the first control module and the fourth pin region.

11. The power supply assembly of claim 1, wherein the input/output pins of the second sub-circuit board are divided into a first pin region, a second pin region, a third pin region, a fourth pin region, a fifth pin region, and a sixth pin region, and the first pin region, the second pin region, the third pin region, the fourth pin region, the fifth pin region and the sixth pin region are respectively electrically connected to the controller of the second control module.

12. The power supply assembly of claim 11, wherein a distance between the controller of the second control module and the sixth pin region is greater than or equal to a distance between the controller of the second control module and the first pin region, a distance between the controller of the second control module and the second pin region, and a distance between the controller of the second control module and the third pin region, and the distance between the controller of the second control module and the sixth pin region is less than a distance between the controller of the second control module and the fourth pin region and a distance between the controller of the second control module and the fifth pin region.
